(19) United States
(12) Patent Application Publication
(10) Pub. No.: US 2013/0163208 A1
(43) Pub. Date: Jun. 27, 2013

(54) ELECTRONIC DEVICE WITH LOCK MECHANISM

(71) Applicant: PENG ZHANG, Shenzhen City (CN)

(72) Inventor: PENG ZHANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/607,902

(22) Filed: Sep. 10, 2012

(30) Foreign Application Priority Data
Dec. 26, 2011 (CN) 201110441234.6

(51) Int. Cl. H05K 5/00

(52) U.S. Cl. 361/724

(57) ABSTRACT

An electronic device includes an enclosure, a cover plate, a battery module, a latching member, a locking member, and a sliding knob connecting the latching member to the locking member. When the sliding knob is located in an original position, the latching member is engaged with the cover plate for securing the cover plate to the enclosure, and the locking member is engaged with the battery module for fixing the battery module to the enclosure. When the sliding knob is slid from the original position to a first unlocked position, the latching member is disengaged from the cover plate for releasing the cover plate from the enclosure. When the sliding knob is slid from the original position to a second locked position, and the locking member is disengaged from the battery module for releasing the battery module from the enclosure.

### BACKGROUND

1. Technical Field

The present disclosure relates to electronic devices and particularly to an electronic device with a lock mechanism.

2. Description of Related Art

An electronic device includes an enclosure, a cover plate, a battery module, a first lock mechanism, and a second lock mechanism. The cover plate is attached to the enclosure and covers the electronic device. The enclosure further defines a receiving slot for receiving and holding the battery module. The first lock mechanism and the second lock mechanism are mounted to the enclosure and secure the cover plate and the battery module to the enclosure. To disassemble, a user has to first dismantle both the first lock mechanism and the second lock mechanism, and then remove the cover plate and the battery module from the enclosure, which is very inconvenient.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an electronic device in accordance with an embodiment.

FIG. 2 is an isometric view of a sliding knob of the electronic device shown in FIG. 1.

FIG. 3 is similar to FIG. 1, but viewed from a different aspect.

FIG. 4 is an assembled view of the electronic device shown in FIG. 1.

FIG. 5 is an assembled view of the electronic device shown in FIG. 3.

FIG. 6 is a cutaway view of the electronic device shown in FIG. 4.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

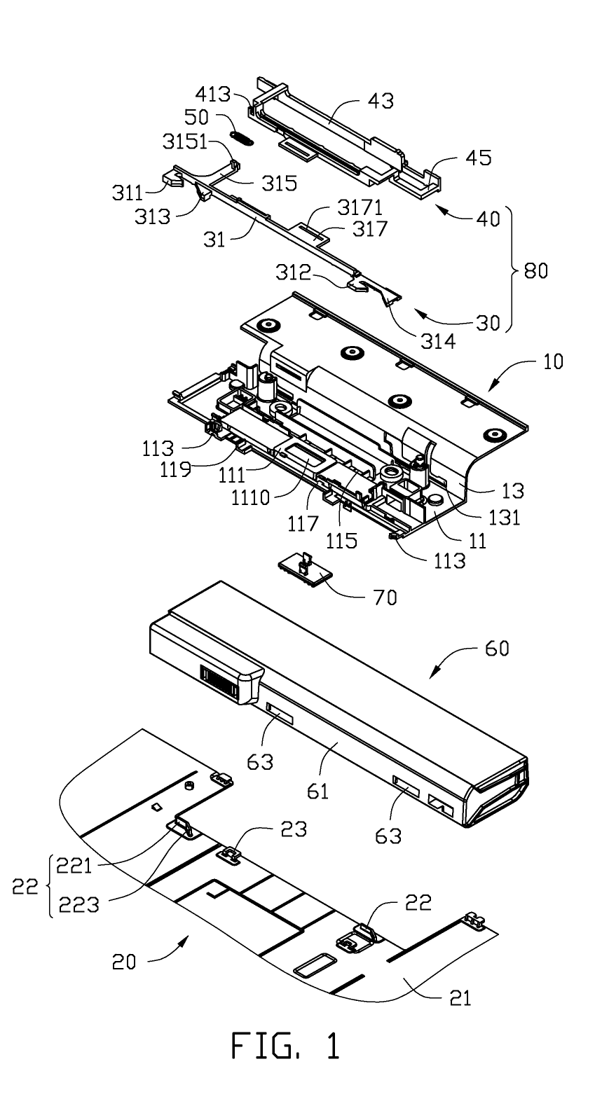

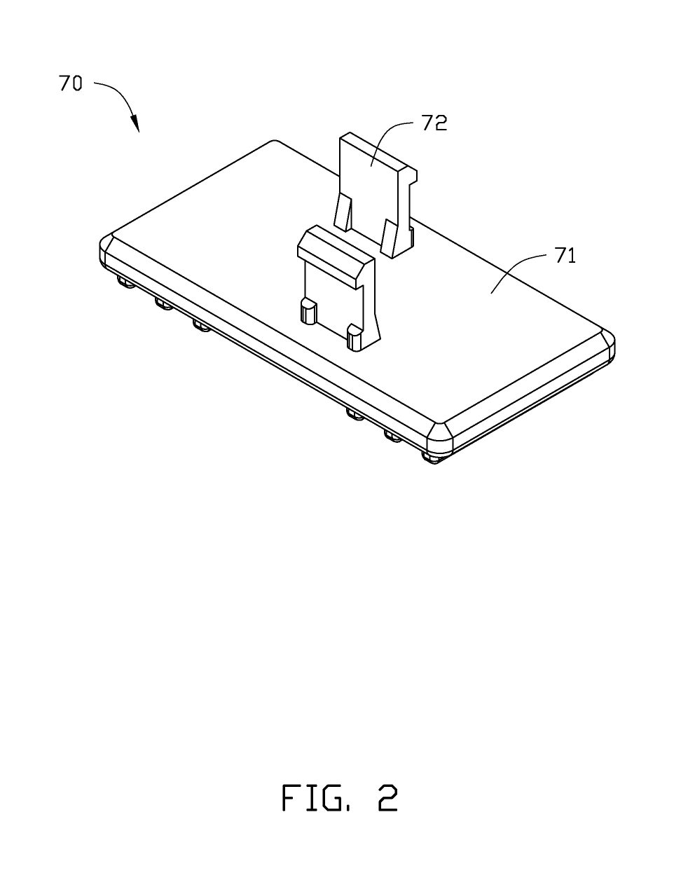

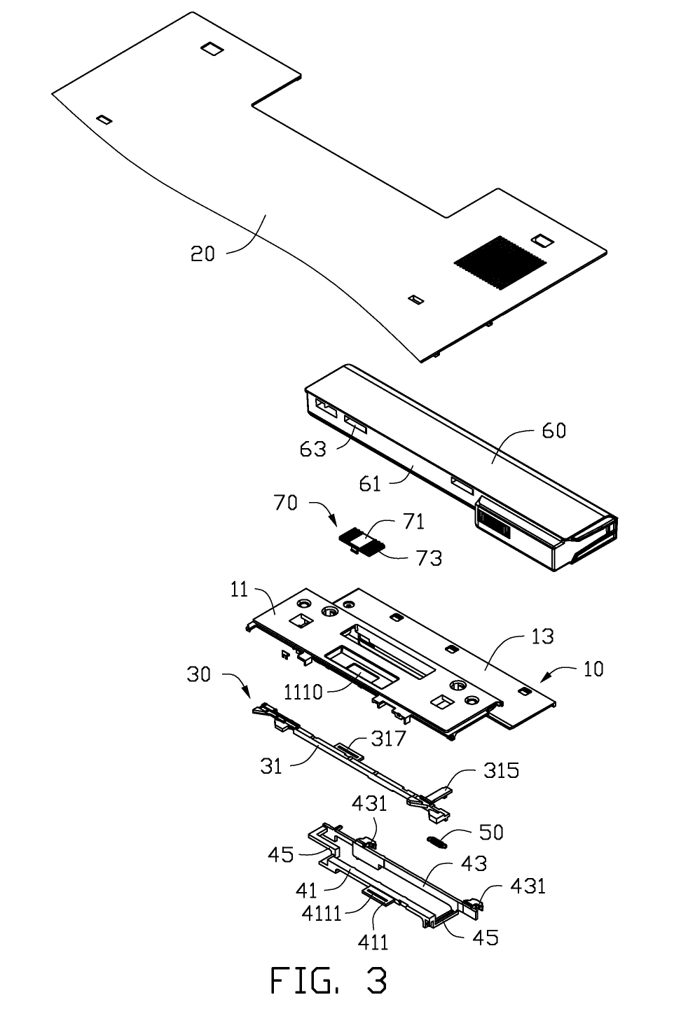

FIGS. 1-3 illustrate an electronic device in accordance with an embodiment. The electronic device includes an enclosure 10, a cover plate 20, a battery module 60, a sliding knob 70, and a lock mechanism 80. In some embodiments, the electronic device is a notebook computer.

The enclosure 10 includes a main frame body 11 and a blocking wall 13 connected to the main frame body 11. The blocking wall 13 is substantially perpendicular to the main frame body 11. The main frame body 11 has a substantially rectangular shape. A receiving portion 111 protrudes from and is located on a front side of the main frame body 11. The receiving portion 111 can receive the sliding knob 70. An installation opening 1110 is defined in the receiving portion 111. Two blocking portions 113 extend from a front edge of the main frame body 11 locating on opposite sides of the receiving portion 111, respectively. Between the two blocking portions 113 and the receiving portion 111 define an elongated sliding way 117 for receiving and holding a latching member 30. A limiting block 119 extends from the front edge of the main frame body 11 adjacent to one of the two blocking portions 113. Two sliding slots 115 are defined in the main frame body 11 for receiving and holding a locking member 40. One of the sliding slots 115 is adjacent to the receiving portion 111, and the other one the sliding slots 115 is adjacent to the blocking wall 13. The blocking wall 13 defines two cutouts 131 communication with one of the two sliding slots 115.

The cover plate 20 includes a U-shaped plate body 21. Two clasping ribs 22 protrude from the plate body 21 adjacent to the edges of the plate body 21. Each of the two clasping ribs 22 includes a first rib portion 221 and a second rib portion 223 extending obliquely from an end of the first rib portion 221. The angle between the first rib portion 221 and the second rib portion 223 is greater than 90 degree. An engaging portion 23 protrudes from the plate body 21 locating between the two clasping ribs 22.

The lock mechanism 80 includes a latching member 30, a locking member 40, and a resilient member 50 connected to the latching member 30 and the locking member 40. The resilient member 50 may be an extension spring.

The latching member 30 includes an elongated main body 31. A first hook 311 and a first resisting piece 313 inside of the first hook 311 extend from the main body 31. The first hook 311 and the first resisting piece 313 are adjacent to a first end of the main body 31. A second hook 312 and a second resisting piece 314 outside of the second hook 312 extend from the main body 31. The second hook 312 and the second resisting piece 314 are adjacent to a second end opposite to the first end of the main body 31. The first hook 311, the first resisting piece 313, the second hook 312, and the second resisting piece 314 are arranged at a first side of the main body 31. A positioning tab 315 and a first latching piece 317 extend from a second side of the main body 31 respectively. A first stopping portion 3151 is located on a distal end of the positioning tab 315 for engaging with the resilient member 50. A first slit 3171 is defined in the first latching piece 317.

The locking member 40 includes a first sliding portion 41, a second sliding portion 43 substantially parallel to the first sliding portion 41, and two connecting portions 45. The two connecting portions 45 are respectively connected to the first sliding portion 41 and the second sliding portion 43. The first sliding portion 41 and the second sliding portion 43 are slidably received in the two sliding slots 115 respectively. A second latching piece 411 extends outwards from the first sliding portion 41. A second slit 4111 is defined in the second latching piece 411. Two clasps 431 are located on the second sliding portion 43 opposite to the second latching piece 411. A second stopping portion 413 is located on an end of the first sliding portion 41 for engaging with the resilient member 50.

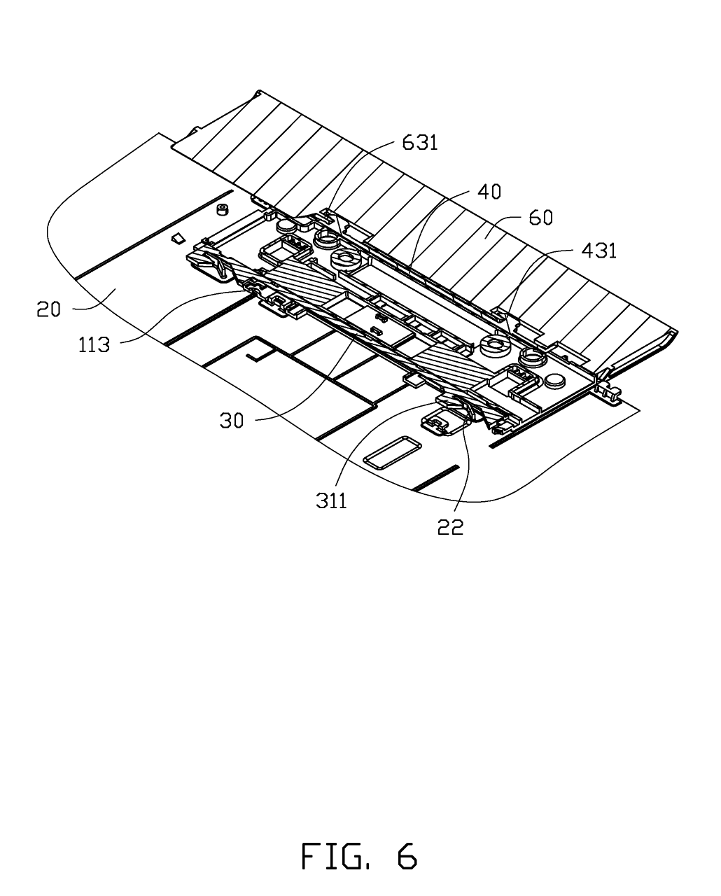

The battery module 60 is substantially rectangular shapes. The battery module 60 includes a sidewall 61 corresponding to the blocking wall 13 of the enclosure 10. The sidewall 61 defines two apertures 63. A blocking tab 631 (shown in FIG. 6) protrudes from a sidewall of each of the two apertures 63 for engaging with each of the two clasps 431.

The sliding knob 70 includes a rectangular plate block 71, two clipping tabs 72, and a wavy operating portion 73. The two clipping tabs 72 protrude from a side of the plate block 71. The operating portion 73 includes a plurality of raised strips arranged on two opposite sides of the plate body 71. The width of the plate block 71 is substantially equal to the width of the receiving portion 111 of the enclosure 10. The length of the plate block 71 is less than the length of the receiving portion 111.

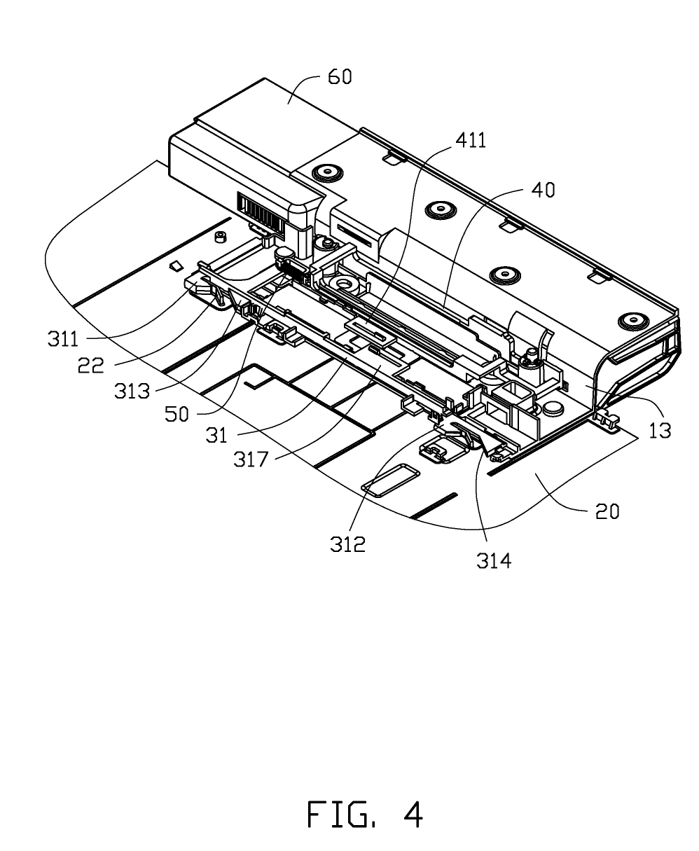

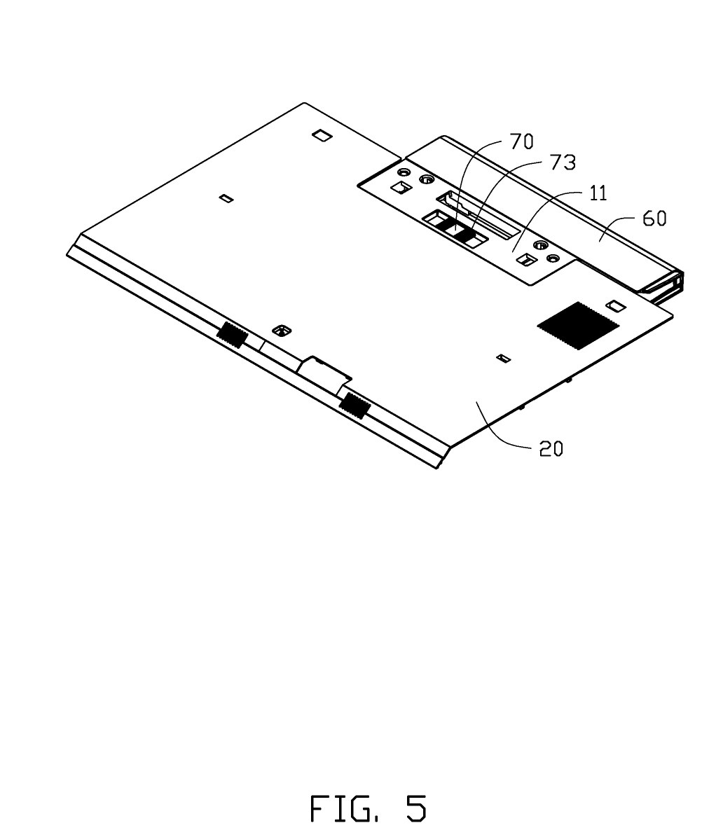

Referring to FIGS. 4 and 5, in assembly, the two clasps 431 extend through the two cutouts 131 of the enclosure 10, respectively. The first sliding portion 41 and the second sliding portion 43 are respectively hold in the two sliding slots 115, and the second sliding portion 43 is adjacent to the blocking wall 13. The second latching piece 411 abuts on a part of the receiving portion 111, and the second slit 4111 is aligned with the installation opening 1110.

When mounting the latching member 30 to the enclosure 10, the main body 31 is held in the sliding way 117. The first latching piece 317 abuts a part of the receiving portion 111, and the first slit 3171 is aligned with the installation opening 1110. The positioning tab 315 is placed on a side of the first sliding portion 41, and the first stopping portion 3151 is in line with the second stopping portion 413. The first resisting piece 313 and the second resisting piece 314 abut the two blocking portions 113 respectively. An end of the resilient member 50 is engaged with the second stopping portion 413 of the locking member 40, and another end of the resilient member 50 is engaged with the first stopping portion 3151 of the latching member 30.

In assembly of the sliding knob 70, the two clipping tabs 72 extend through the installation opening 1110 of the enclosure 10, one of the clipping tabs 72 extends through the first slit 3171 of the latching member 30. The locking member 40 is pushed, and the resilient member 50 is resiliently deformed, until the other one of the clipping tabs 72 extends through the second slit 411 of the locking member 40. The locking member 40 is released, and the resilient member 50 elastically rebounds to engage the two clipping tabs 72 with the first latching piece 317 and the second latching piece 411 respectively.

When installing the cover plate 20, an acting force is applied to the operating portion 73 of the sliding knob 70 to actuate the sliding knob 70 to slide from a original position to a first unlocked position. The latching member 30 is slide towards a first direction parallel to the blocking wall 13, until the second rib portion 223 of the two clasp ribs 22 block the first resisting piece 313 and the second resisting piece 314 respectively. The cover plate 20 is moved towards and closed to the main frame body 11 of the enclosure 10. The engaging portion 23 is engaged with the main frame body 11 and abuts the limiting block 119. The sliding knob 70 is released and slid from the first unlocked position to the original position. The latching member 30 is slid towards a second direction opposite to the first direction by elastic forces exerted by the resilient member 50, until the first hook 311 and the second hook 312 are engaged with the first rib portion 221 of the two clasp ribs 22 respectively. Thus, the cover plate 20 is thereby installed on the enclosure 10.

In assembly of the battery module 60 is moved towards and close to the blocking wall 13. An acting force is applied to the operating portion 73 of the sliding knob 70 to actuate the sliding knob 70 to slide from the original position to a second unlocked position. The latching member 30 is slid towards the second direction, until the two clasps 431 of the locking member 40 are aligned with the two apertures 63 of the battery module 60. The two clasps 431 are inserted into the two apertures 63 respectively. The operating portion 73 is released and slide from the second unlocked position to the original position. The locking member 40 is slid towards the first direction by elastic forces exerted by the resilient member 50, until the two clasps 431 are engaged with the blocking tab 631 of the two apertures 63 respectively.

In disassembly of the battery module 60, an acting force is applied to the operating portion 73 of the sliding knob 70 to slide from the original position to the second unlocked position. The locking member 40 is slid towards the second direction, until the two clasps 431 are disengaged from the blocking tab 631 of the two apertures 63. Thus, the battery module 60 is not fixed and can be removed from the enclosure 10 easily.

In disassembly of the cover plate 20, an acting force is applied to the operating portion 73 of the sliding knob 70 to slide from the original position to the first unlocked position. The latching member 30 is slid towards the first direction, until the first hook 311 and the second hook 312 are disengaged from the first rib portion 221 of the two clasp ribs 22, and move the cover plate 20 outwards. Thus, the cover plate 20 is removed from the enclosure 10.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. An electronic device comprising:
an enclosure;
a cover plate;
a battery module;
a latching member;
a locking member; and
a sliding knob, the sliding knob connecting the latching member to the locking member,
wherein when the sliding knob is located in an original position, the latching member is engaged with the cover plate and secures the cover plate to the enclosure, and the locking member is engaged with the battery module for fixing the battery module to the enclosure; when the sliding knob is slid from the original position to a first unlocked position, the latching member is disengaged from the cover plate for releasing the cover plate from the enclosure; when the sliding knob is slid from the original position to a second locked position, and the locking member is disengaged from the battery module for releasing the battery module from the enclosure.

2. The electronic device of claim 1 further comprises a resilient member connecting the latching member to the locking member, wherein the resilient member biases the latching member to slide from the first unlocked position to the original position or biases the locking member to slide from the second unlocked position to the original position.

3. The electronic device of claim 2, wherein the latching member comprises a first stopping portion, the locking member comprises a second stopping portion, and the first stopping portion is aligned with the second stopping portion; one end of the resilient member is engaged with the first stopping portion, and another end of the resilient member is engaged with the second stopping portion.

4. The electronic device of claim 1, wherein the enclosure defines an elongated sliding way, the latching member comprises an elongated main body, and the main body is slidably received in the sliding way.

5. The electronic device of claim 4, wherein at least one hook and at least one resisting piece are located on the main body of the latching member, the cover plate comprises at least one clasp rib, the at least one clasp rib comprises a first rib and a second rib connected to the first rib; when the latching member is in the original position, the at least one hook is engaged with the first rib; and when the latching member is in the first unlocked position, the at least one resisting piece abuts the second rib.

6. The electronic device of claim 5, wherein an angle defined between the first rib portion and the second rib portion is greater than 90 degree.

7. The electronic device of claim 1, wherein the enclosure defines two sliding slots, the locking member comprises a first sliding portion and a second sliding portion, and each of the first sliding portion and the second sliding portion is slidably received in each of the two sliding slots.

8. The electronic device of claim 1, wherein the battery module defines two apertures, the locking member comprises two clasps, the enclosure defines two cutouts, and each of the two clasps extends through each of the two cutouts to be engaged in each of the two apertures.

9. The electronic device of claim 8, wherein a blocking tab protrudes from a side wall of each of the two apertures, and the each of the two clasps is engaged with the blocking tab.

10. The electronic device of claim 1, wherein the sliding knob comprises two clipping tabs; the enclosure defines an installation opening; the latching member comprises a first latching piece with a first slit, the locking member comprises a second latching piece with a second slit; one of the two clipping tabs extends through the installation opening and the first slit to engage with the first latching piece, and another one of the two clipping tabs extends through the installation opening and the second slit to engage with the second latching piece.

11. An electronic device comprising:
an enclosure;
a cover plate;
a battery module;
a latching member;
a locking member;
a sliding knob, the sliding knob connecting the latching member to the locking member; and
a resilient member, the sliding knob elastically connecting the latching member to the locking member,
wherein when the sliding knob is located in a original position, the latching member is engaged with the cover plate for securing the cover plate to the enclosure, and the locking member is engaged with the battery module for fixing the battery module to the enclosure; when the sliding knob is slid from the original position to a first unlocked position, the latching member is disengaged from the cover plate for releasing the cover plate from the enclosure; when the sliding knob is slid from the original position to a second locked position, the locking member is disengaged from the battery module for releasing the battery module from the enclosure; and the resilient member biases the latching member to slide from the first unlocked position to the original position or biases the locking member to slide from the second unlocked position to the original position.

12. The electronic device of claim 11, wherein the latching member comprises a first stopping portion, the locking member comprises a second stopping portion, and one end of the resilient member is engaged with the first stopping portion, and another end of the resilient member is engaged with the second stopping portion.

13. The electronic device of claim 11, wherein the cover plate comprises an engaging portion, and the engaging portion is engaged with the enclosure.

14. The electronic device of claim 11, wherein the enclosure defines an elongated sliding way, the latching member comprises an elongated main body, and the main body is slidably received in the sliding way.

15. The electronic device of claim 14, wherein at least one hook and at least one resisting piece are located on the main body of the latching member, the cover plate comprises at least one clasp rib, the at least one clasp rib comprises a first rib and a second rib connected to the first rib; when the latching member is in the original position, the at least one hook is engaged with the first rib; and when the latching member is in the first unlocked position, the at least one resisting piece abuts the second rib.

16. The electronic device of claim 15, wherein an angle between the first rib portion and the second rib portion is greater than 90 degree.

17. The electronic device of claim 11, wherein the enclosure defines two sliding slots, the locking member comprises a first sliding portion and a second sliding portion, and each of the first sliding portion and the second sliding portion is slidably received in each of the two sliding slots.

18. The electronic device of claim 11, wherein the battery module defines two apertures, the locking member comprises two clasps, the enclosure defines two cutouts, and each of the two clasps extends through each of the two cutouts to be engaged in each of the two apertures.

19. The electronic device of claim 18, wherein a blocking tab protrudes from a side wall of each of the two apertures, and the each of the two clasps is engaged with the blocking tab of each of the two apertures.

20. The electronic device of claim 11 , wherein the sliding knob comprises two clipping tabs; the enclosure defines an installation opening; the latching member comprises a first latching piece with a first slit, the locking member comprises a second latching piece with a second slit; one of the two clipping tabs extends through the installation opening and the first slit to engage with the first latching piece, and another one of the two clipping tabs extends through the installation opening and the second slit to engage with the second latching piece.
